(19) United States
(12) Patent Application Publication
(10) Pub. No.: US 2013/0161688 A1
(43) Pub. Date: Jun. 27, 2013

(54) SEMICONDUCTOR DEVICE AND METHOD OF MANUFACTURING THE SAME

(71) Applicant: SAMSUNG ELECTRO-MECHANICS CO., LTD., Suwon (KR)

(72) Inventors: Dong Soo SEO, Suwon (KR); Jae Hoon PARK, Suwon (KR)

(73) Assignee: SAMSUNG ELECTRO-MECHANICS CO., LTD., Suwon (KR)

(21) Appl. No.: 13/678,336

(22) Filed: Nov. 15, 2012

(30) Foreign Application Priority Data
Dec. 26, 2011 (KR) 10-2011-0142689

(51) Int. Cl. H01L 29/739

(52) U.S. Cl. CPC H01L 29/7395
USPC 257/139; 438/138

(57) ABSTRACT

There are provided a semiconductor device and a method of manufacturing the same. The semiconductor device includes a semiconductor substrate having a front surface and a back surface and having a p-type impurity layer, a low-concentration n-type impurity layer, and an n-type impurity layer disposed in a backward direction from the front surface thereof, the n-type impurity layer having a high-concentration p-type impurity region therein and the n-type impurity layer and the high-concentration p-type impurity region being exposed to the back surface; and a deep trench formed vertically in the semiconductor substrate to be open to the front surface of the semiconductor substrate and having a bottom surface connected to the high-concentration p-type impurity region. Here, an activation ratio of impurities may be increased and damages to a wafer may be prevented during a thin film process.

### CROSS-REFERENCE TO RELATED APPLICATIONS

This application claims the priority of Korean Patent Application No. 10-2011-0142689 filed on Dec. 26, 2011, in the Korean Intellectual Property Office, the disclosure of which is incorporated herein by reference.

### BACKGROUND OF THE INVENTION

1. Field of the Invention

The present invention relates to a semiconductor device and a method of manufacturing the same.

2. Description of the Related Art

In recent years, an insulated gate bipolar transistor (hereinafter, referred to as an “IGBT”) has prevalently been used as a power supply device in a large-capacity motor drive, an induction heating device, a welding machine, or the like. The IGBT has a significant structural difference from a metal oxide semiconductor (MOS), in that a large amount of current may flow in a PNP transistor operation, due to the presence of a P layer on a back side thereof.

In the case of a non punch-through IGBT (NPT-IGBT) or a field stop IGBT (FS-IGBT), initially, front surface processing is completed, and subsequently, back surface processing is performed. During the front surface processing, a process of forming a metal film on a front surface of a semiconductor substrate is performed, and during the back surface processing, ion implantation and thermal diffusion processes for forming a field stop layer are performed. That is, in order to form a collector on a back surface of the semiconductor substrate, p-type impurities are generally implanted into the back surface of the semiconductor substrate and then, are subjected to thermal diffusion.

In the case of the field-stop IGBT (FS-IGBT), a product having a thickness of 60 to 75 μm is required, such that an importance of an ultra thin wafer process has been increased. However, the ultra thin wafer process may lead to damage of the wafer while an additional process is being performed on a very thin wafer after polishing.

In the case of a reverse conducting IGBT (RC-IGBT), a need exists for a photo etching process (PEP) capable of alternately disposing a p-type impurity region and an n-type impurity region on the back side of the semiconductor substrate. However, back surface processing is conducted in a thin wafer state and therefore, a wafer may be damaged during the PEP.

### SUMMARY OF THE INVENTION

An aspect of the present invention provides a semiconductor device and a method of manufacturing the same capable of increasing an activation ratio of impurities and preventing a wafer from being damaged during a thin film process.

According to an aspect of the present invention, there is provided a semiconductor device, including: a semiconductor substrate having a front surface and a back surface and having a p-type impurity layer, a low-concentration n-type impurity layer, and an n-type impurity layer disposed in a backward direction from the front surface thereof, the n-type impurity layer having a high-concentration p-type impurity region therein and the n-type impurity layer and the high-concentration p-type impurity region being exposed to the back surface; and a deep trench formed vertically in the semiconductor substrate to be open to the front surface of the semiconductor substrate and having a bottom surface connected to the high-concentration p-type impurity region.

The semiconductor substrate may be a semiconductor wafer.

The p-type impurity region and the low-concentration n-type impurity layer may have an n-type impurity layer formed therebetween.

The deep trench may have an oxide film formed on an inner wall thereof.

The oxide film may be protruded outwardly of the front surface of the semiconductor substrate.

The oxide film may be formed of silicon oxide.

The deep trench may be filled with a conductive material.

The conductive material may include polysilicon.

The deep trench and an adjacent deep trench may have a gate trench formed therebetween, the gate trench being open to the front surface of the semiconductor substrate, and a bottom portion of the gate trench may be connected to the low-concentration n-type impurity layer.

The gate trench may have an oxide film formed on an inner wall thereof.

The oxide film may be protruded outwardly of the front surface of the semiconductor substrate.

The protruded oxide film may extend to a portion of the front surface of the semiconductor substrate.

The oxide film may be formed of silicon oxide.

The gate trench may be filled with a conductive material.

The conductive material may include polysilicon.

A high-concentration p-type or n-type impurity region maybe formed around an opening of the gate trench of the front surface of the semiconductor substrate.

The n-type impurity layer may be doped with n-type impurities including group V elements.

The p-type impurity layer and the p-type impurity region may be doped with p-type impurities including group III elements.

The front surface of the semiconductor substrate may be coated with a front metal film serving as an emitter electrode.

The front metal film may be formed of aluminum or titanium.

The back surface of the semiconductor substrate may be coated with a back metal film serving as a collector electrode.

The back metal film may be formed of nickel or silver.

According to another aspect of the present invention, there is provided a method of manufacturing a semiconductor device, including: preparing a semiconductor substrate having a front surface and a back surface and doped with low-concentration n-type impurities; forming a deep trench vertically in the semiconductor substrate to be open to the front surface of the semiconductor substrate; forming an n-type impurity layer by implanting n-type impurity ions into a bottom surface of the deep trench and performing a heat treatment thereon; forming a high-concentration p-type impurity region within the n-type impurity layer by implanting p-type impurity ions into the bottom surface of the deep trench and performing a heat treatment thereon; and forming a front metal film serving as an emitter electrode on the front surface of the semiconductor substrate.

In the forming of the deep trench, the deep trench may be formed by an etching process.

In the forming of the n-type impurity layer, the heat treatment may be performed at 800 to 1200° C.

In the forming of the high-concentration p-type impurity region, the heat treatment may be performed at 800 to 1200° C.

The front metal film may be formed of aluminum or titanium.

The n-type impurity layer may be doped with n-type impurities including group V elements.

The p-type impurity region may be doped with p-type impurities including group III elements.

The semiconductor substrate may be a semiconductor wafer.

The method may further include forming a gate trench open to the front surface of the semiconductor substrate and connected to a low-concentration n-type impurity layer, after the forming of the high-concentration p-type impurity region.

The method may further include forming an oxide film in the deep trench and the gate trench after the forming of the gate trench.

The method may further include burying a conductive material in the deep trench and the gate trench after the forming of the oxide film.

The conductive material may include polysilicon.

The method may further include performing back surface processing by polishing the back surface of the semiconductor substrate to expose the n-type impurity layer and the p-type impurity region after the burying of the conductive material.

The method may further include forming a back metal film serving as a collector electrode on the back surface of the semiconductor substrate, after the back surface processing.

The back metal film may be formed of nickel or silver.

### BRIEF DESCRIPTION OF THE DRAWINGS

The above and other aspects, features and other advantages of the present invention will be more clearly understood from the following detailed description taken in conjunction with the accompanying drawings, in which:

FIG. 1 is a cross-sectional view of a semiconductor device according to an embodiment of the present invention; and

FIGS. 2 to 7 are diagrams showing a process of manufacturing a semiconductor device according to an embodiment of the present invention, wherein FIG. 2 is a diagram showing a semiconductor substrate in which a deep trench is formed, FIG. 3 is a diagram showing the semiconductor substrate in which an impurity region is formed, FIG. 4 is a diagram showing the semiconductor substrate in which a gate trench is formed, FIG. 5 is a diagram showing the semiconductor substrate in which the trenches are filled with an oxide film and a conductive material, FIG. 6 is a diagram showing the semiconductor substrate of which a back surface is polished, and FIG. 7 is a diagram showing the semiconductor substrate on which a front metal film and a back metal film are formed.

### DETAILED DESCRIPTION OF THE EMBODIMENTS

Embodiments of the present invention will now be described in detail with reference to the accompanying drawings.

The embodiments of the present invention may be modified in many different forms and the scope of the present invention should not be limited to the embodiments set forth herein.

Rather, these embodiments are provided so that this disclosure will be thorough and complete, and will fully convey the concept of the invention to those skilled in the art.

In the drawings, the shapes and dimensions of components may be exaggerated for clarity, and the same reference numerals will be used throughout to designate the same or like components.

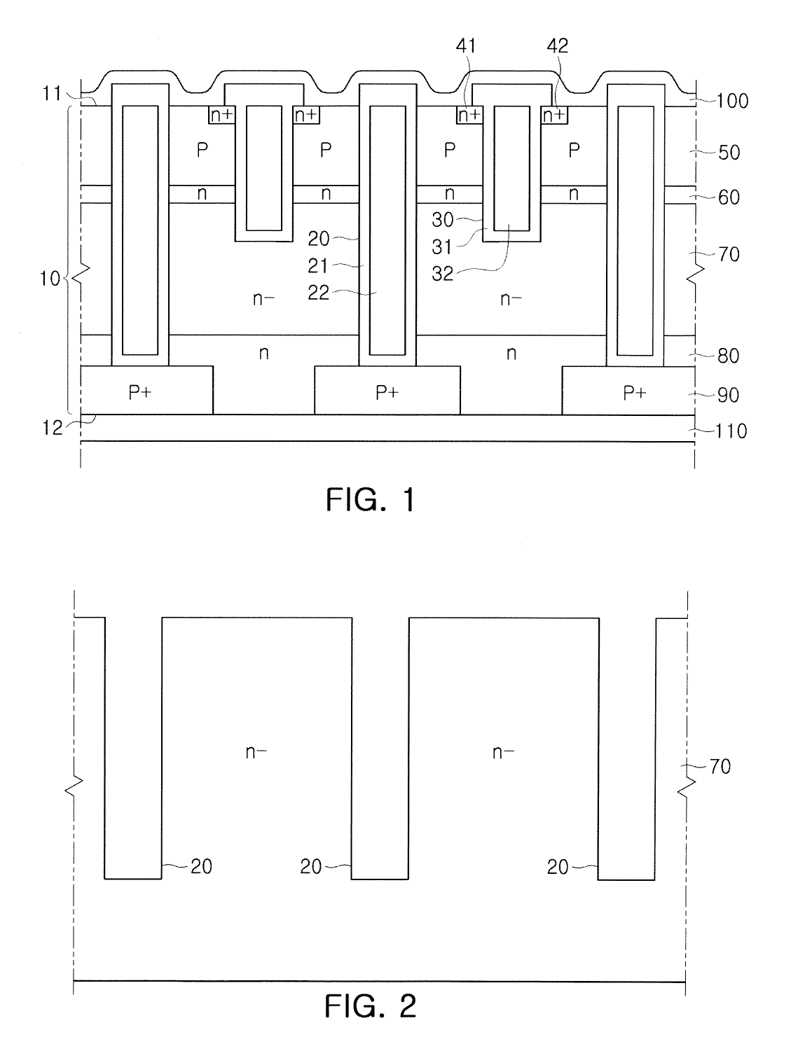

FIG. 1 is a cross-sectional view of a semiconductor device according to an embodiment of the present invention; and FIGS. 2 to 7 are diagrams showing a process of manufacturing a semiconductor device according to the embodiment of the present invention.

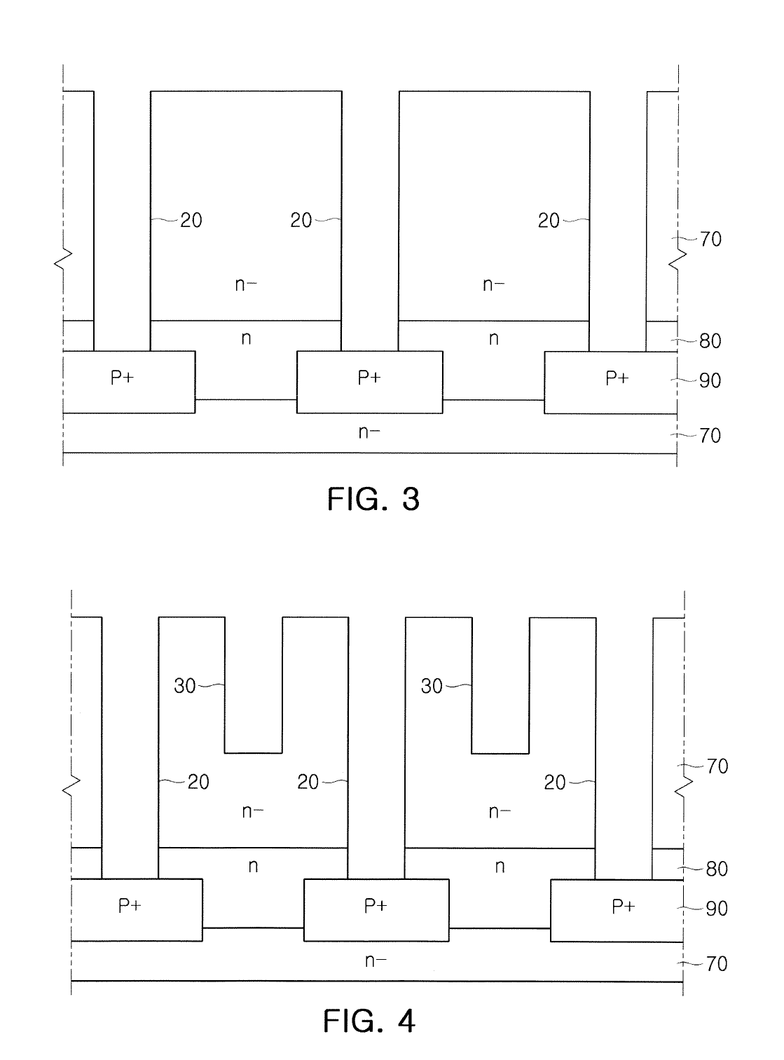

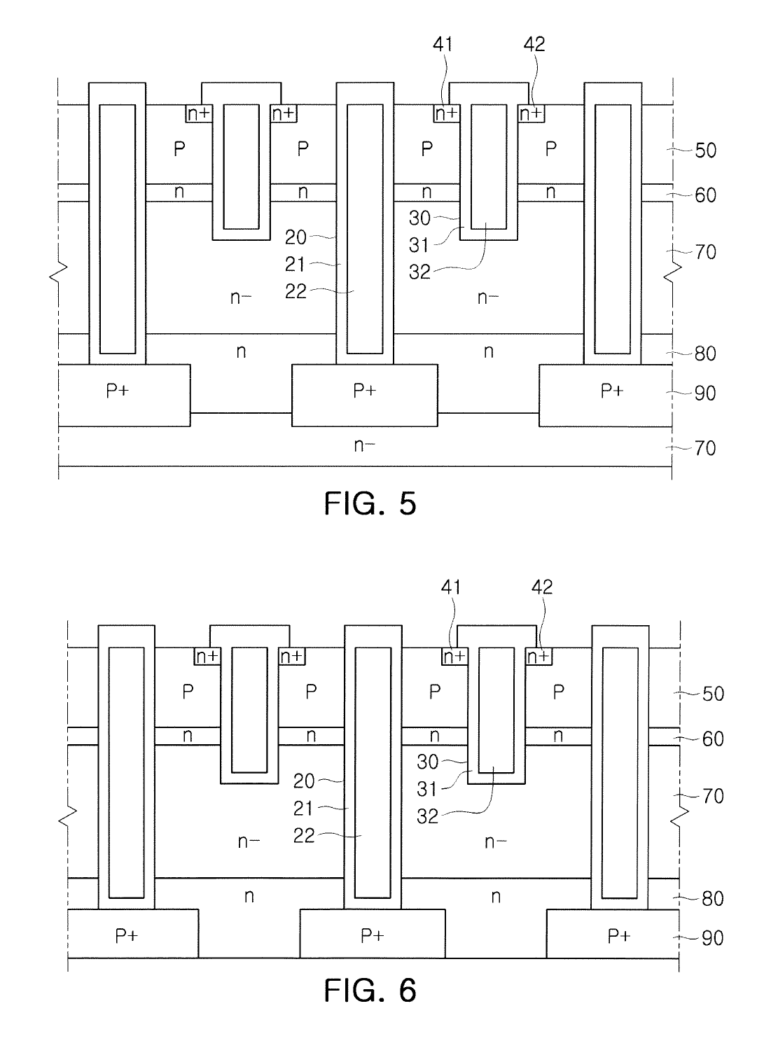

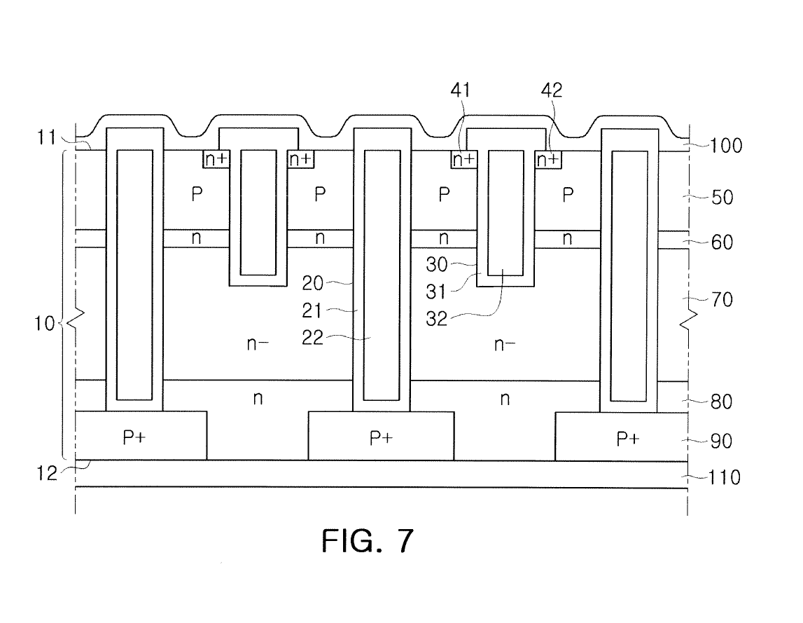

FIG. 2 is a diagram showing a semiconductor substrate in which a deep trench is formed, FIG. 3 is a diagram showing the semiconductor substrate in which an impurity region is formed, FIG. 4 is a diagram showing the semiconductor substrate in which a gate trench is formed, FIG. 5 is a diagram showing the semiconductor substrate in which the trenches are filled with an oxide film and a conductive material, FIG. 6 is a diagram showing the semiconductor substrate of which a back surface is polished, and FIG. 7 is a diagram showing the semiconductor substrate on which a front metal film and a back metal film are formed.

Referring to FIG. 1, an embodiment of the present invention may include a semiconductor substrate 10 and a deep trench 20.

The semiconductor substrate 10 may have a front surface 11 and a back surface 12.

A p-type impurity layer 50, a low-concentration n-type impurity layer 70, and an n-type impurity layer 80 may be disposed in a backward direction from the front surface 11 of the semiconductor substrate 10. A high-concentration p-type impurity region 90 may be formed in the n-type impurity layer 80. The n-type impurity layer 80 and the high-concentration p-type impurity region 90 may be exposed to the back surface 12.

In this manner, the semiconductor substrate 10 may be formed to have a PNP transistor structure.

In the drawings, “p+” denotes that p-type impurities are doped at a high concentration, “n+” denotes that n-type impurities are doped at a high concentration, and “n−” denotes that n-type impurities are doped at a low concentration.

The n-type impurity layer 80 is referred to as a field stop layer. When overvoltage is applied to the semiconductor device, the semiconductor device may be damaged. Therefore, the field stop layer may block electric field to protect the semiconductor device.

The semiconductor substrate 10 may further include an n-type impurity layer 60 between the p-type impurity layer 50 and the low-concentration n-type impurity layer 70. The n-type impurity layer 60 may serve to store carriers (electrons or holes).

The n-type impurities may include group V elements, specifically, phosphor. The p-type impurities may include group III elements, specifically, boron.

The semiconductor substrate 10 may be a semiconductor wafer, in more detail, may be a silicon wafer. The low-concentration n-type impurity layer 70 of the semiconductor substrate 10 may be formed by doping the n-type impurities during a process of manufacturing the silicon wafer.

The deep trench 20 may be formed vertically in the semiconductor substrate 10 to be open to the front surface 11 of the semiconductor substrate 10. The deep trench 20 may be formed in the semiconductor substrate 10, while forming a trough.

A bottom surface of the deep trench 20 maybe connected to the high-concentration p-type impurity region 90. The bottom surface of the deep trench 20 indicates a point at which the deep trench 20 is stopped. The reason is that the high-concentration p-type impurity region 90 is formed through the deep trench 20. That is, impurity ions are implanted into the bottom portion of the deep trench 20 and are subjected to thermal diffusion, thereby forming the high-concentration p-type impurity region 90.

Similarly, the n-type impurity layer 80 maybe formed by the ion implantation through the deep trench 20 and the thermal diffusion.

An inner wall of the deep trench 20 may be coated with an oxide film 21, and the oxide film 21 maybe formed of silicon oxide. When a silicon wafer is used as the semiconductor substrate 10, an oxidizing gas may simply flow into the inner wall of the deep trench 20 to thereby form the oxide film 21. Specifically, the oxide film 21 may be SiO₂.

The oxide film 21 may be formed on the front surface 11 of the semiconductor substrate 10 as well as the inner wall of the deep trench 20. The oxide film formed on the front surface 11 of the semiconductor substrate 10 may be removed by etching.

The inside of the deep trench 20 may be filled with a conductive material 22. Specifically, the conductive material 22 may include polysilicon.

Since the deep trench 20 is in an electrical floating state, resistance components may be reduced relative to regions occupied by the deep trench 20. As a result, a VCE (sat) value of the semiconductor device may be lowered.

The oxide film 21 may be protruded outwardly of the front surface 11 of the semiconductor substrate 10. The inside of the deep trench 20 having the oxide film 21 formed thereon, is filled with the conductive material 22 and then, the oxide film 21 is formed thereon.

A gate trench 30 may be formed between the deep trenches 20. The gate trench 30 is open to the front surface 11 of the semiconductor substrate 10 and a bottom portion thereof may be connected to the low-concentration n-type impurity layer 70.

The inside of the gate trench 30 may be filled with a conductive material 32. Specifically, the conductive material 32 may include polysilicon. The conductive material 32 filling the inside of the gate trench 30 may serve as a gate.

An inner wall of the gate trench 30 may be coated with an oxide film 31 and the oxide film 31 may be formed by the same method as the method used in the forming of the deep trench 20. The oxide film 31 may be silicon oxide.

The gate may be completely isolated from the outside by the oxide film 31. That is, the gate is electrically insulated.

The oxide film 31 may be protruded outwardly of the front surface 11 of the semiconductor substrate 10 and the protruded oxide film may be formed to extend to a portion of the front surface 11 of the semiconductor substrate 10. Since the protruded oxide film extends to a portion of the front surface 11 of the semiconductor substrate 10, it may isolate the gate from the outside more effectively.

High-concentration n-type or p-type impurity regions 41 and 42 may be formed around an opening of the gate trench 30 of the front surface 11 of the semiconductor substrate 10. FIG. 1 shows only the n-type impurity region, but the embodiment of the present invention is not limited thereto.

A front metal film 100 serving as an emitter electrode may be formed on the front surface 11 of the semiconductor substrate 10. The front metal film 100 may be formed of a material having sufficient conductivity without being particularly limited so long as it can serve as the emitter electrode. Specifically, the conductive material may include aluminum or titanium.

A back metal film 110 serving as a collector electrode may be formed on the back surface 12 of the semiconductor substrate 10. The back metal film 110 may be formed of a material having sufficient conductivity without being particularly limited so long as it can serve as the collector electrode. Specifically, the conductive material may include nickel or silver.

Hereinafter, a method of manufacturing a semiconductor device according to another embodiment of the present invention will be described in detail with reference to FIGS. 2 through 7.

A method of manufacturing a semiconductor device according to the embodiment of the present invention may include preparing the semiconductor substrate 10, forming the deep trench 20, forming the n-type impurity layer 80; forming the high-concentration p-type impurity region 90; and forming the front metal film 100.

Referring to FIG. 2, in the preparing of the semiconductor substrate 10, the semiconductor substrate 10 may have the front surface 11 and the back surface 12 and be doped with low-concentration n-type impurities.

The semiconductor substrate 10 maybe a semiconductor wafer, and specifically, may be a silicon wafer.

The n-type impurities may include group V elements, specifically, phosphor.

Next, referring to FIG. 2, in the forming of the deep trench 20, the deep trench 20 may be formed vertically in the semiconductor substrate 10 and be open to the front surface 11 of the semiconductor substrate 10. The deep trench 20 may be formed by etching.

Next, referring to FIG. 3, in the forming of the n-type impurity layer 80, n-type impurity ions may be implanted into a bottom surface of the deep trench 20 and then be heat-treated, thereby forming the n-type impurity layer 80. The n-type impurities may include group V elements, specifically, phosphor.

The heat treatment may be performed at 800 to 1200° C. The heat treatment of the impurity ions is performed at a sufficient higher temperature than a melting point of the front metal film 100, thereby increasing an activation ratio of the impurity ions.

Next, referring to FIG. 3, in the forming of the high-concentration p-type impurity region 90, p-type impurity ions may be implanted into the bottom surface of the deep trench 20 and then be heat-treated, thereby forming the high-concentration p-type impurity region 90. The high concentration p-type impurity region 90 may be formed within the n-type impurity layer 80.

The heat treatment may be performed at 800 to 1200° C. The heat treatment of the impurity ions is performed at a sufficient higher temperature than a melting point of the front metal film 100, thereby increasing an activation ratio of the impurity ions. The p-type impurities may include group III elements, specifically, boron.

Next, referring to FIG. 7, in the forming of the front metal film 100, the front metal film 100 serving as an emitter electrode may be formed on the front surface 11 of the semiconductor substrate 10. The front metal film 100 may include aluminum or titanium.

According to the embodiment of the present invention, the front metal layer 100 is formed after the n-type impurity layer 80 and the high-concentration p-type impurity region 90 are formed.

Hereinafter, the advantageous effects of the embodiment of the present invention will be described in comparison with a case in which the front metal film 100 is initially formed, that is, a case in which the gate trench 30 and the front metal film 100 are formed on the front surface 11 of the semiconductor substrate 10 and then the impurity ions are implanted into the back surface 12 of the semiconductor substrate 10 and are subjected to thermal diffusion to thereby form the n-type impurity layer 80 and the high-concentration p-type impurity region 90.

First, an activation ratio of the impurity ions may be increased.

The impurity ions may be diffused into the semiconductor substrate 10 through the thermal diffusion process and may be activated. As the temperature of the thermal diffusion process is increased, the activation ratio of the impurity ions may be increased. However, in the case in which the front metal film 100 is initially formed, there may be a restriction in that the thermal diffusion process cannot be performed at a temperature higher than the melting point of the front metal film 100.

In a case in which aluminum is used as the material of the front metal film 100, the temperature of the thermal diffusion process cannot be increased above approximately 650° C. that is a melting point of aluminum. As a result, the activation ratio of the implanted impurity ions may be low due to the low thermal diffusion temperature. For example, when the thermal diffusion process is performed at approximately 500° C., the activation ratio of the impurity ions may be about 5 to 10%. When the thermal diffusion process is performed at 800 to 1200° C., the activation ratio of the impurity ions may be increased to 90% or more. However, there is a restriction in raising the thermal diffusion temperature due to the front metal film 100.

On the other hand, in the case of the embodiment of the present invention, the impurity ions are implanted through the deep trench 20 open to the front surface 11 of the semiconductor substrate 10 and are activated, and then, the front metal film 100 is formed on the front surface 11 of the semiconductor substrate 10. Accordingly, the temperature of the thermal diffusion process may not be restricted due to the front metal layer 100.

Therefore, the temperature of the thermal diffusion process may sufficiently rise to 1000° C. or more and the activation ratio of the impurity ions may rise to 90% or more. In addition, since the activation ratio may be controlled by temperature, the VCE (sat) may be reduced without using an expensive device such as a laser annealing device, or the like.

Second, back surface processing maybe simplified and damages of the wafer may be prevented during the back surface processing.

In the case of the embodiment of the present invention, the n-type impurity layer 80 and the high-concentration p-type impurity region 90 are formed during front surface processing and then, the back surface 12 of the semiconductor substrate 10 is polished to have a desired thickness and a collector electrode is formed through the back surface processing. That is, impurity ion implantation and thermal diffusion may not be performed during the back surface processing.

According to the related art, the back surface of the semiconductor substrate is polished and impurities are implanted into the polished back surface and are thermally diffused. However, these processes are omitted in the embodiment of the present invention. Therefore, processes performed on the thinned substrate after polishing may be reduced to thereby significantly reduce a risk of damages of the wafer.

In particular, in the case of the RC-IGBT, a photo etching process (PEP) is required so as to alternately dispose the high-concentration p-type impurity region 90 and the n-type impurity region 80 on the back surface 12 of the semiconductor substrate 10. Due to the PEP process, the wafer may be damaged.

The high-concentration p-type impurity region 90 may be selectively formed through the deep trench 20 open to the front surface 11 of the semiconductor substrate 10, such that there is no need to use the PEP process. As a result, process simplification and the prevention of damages to the wafer can be achieved.

Referring to FIG. 4, after the forming of the high-concentration p-type impurity region 90, the gate trench 30 may be formed to be open to the front surface 11 of the semiconductor substrate 10 and be connected to the low-concentration n-type impurity layer 70.

Referring to FIG. 5, after the forming of the gate trench 30, the oxide films 21 and 31 may be formed in the deep trench 20 and the gate trench 30, respectively. The oxide films 21 and 31 may be formed of silicon oxide.

Referring to FIG. 5, after the forming of the oxide films 21 and 31, the conductive materials 22 and 32 may be buried in the deep trench 20 and the gate trench 30. The conductive materials 22 and 32 may include polysilicon.

Referring to FIG. 6, after the burying of the conductive materials in the trenches 20 and 30, the back surface 12 of the semiconductor substrate 10 is polished through back surface processing to thereby allow the n-type impurity layer 80 and the high-concentration p-type impurity region 90 to be exposed.

The n-type impurity layer 80 and the high-concentration p-type impurity region 90 may be exposed to the back surface 12 of the semiconductor substrate 10 by polishing the back surface 12 of the semiconductor substrate 10.

According to the embodiment of the present invention the back surface processing may be simplified, as compared with the case of forming the n-type impurity layer and the high-concentration p-type impurity region by implanting ions into the back surface of the semiconductor substrate and thermally diffusing the ions.

Since the n-type impurity layer 80 and the high-concentration p-type impurity region 90 are formed through the deep trench 20, only the simple polishing process is required in the back surface processing.

Referring to FIG. 7, after the back surface processing, the back metal film 110 serving as the collector electrode may be formed on the back surface 12 of the semiconductor substrate 10. The back metal film 110 may include nickel or silver.

The other features of the semiconductor substrate 10, the n-type or p-type impurity region, the n-type or p-type impurity layer, the front metal film, the back metal film, and the like, are identical to those described in the above-mentioned embodiment of the present invention.

As set forth above, according to embodiments of the present invention, a semiconductor device and a method of manufacturing the same can allow for an increase in an activation ratio of impurities, prevention of damages to a wafer during a thin film process, and process simplification.

While the present invention has been shown and described in connection with the embodiments, it will be apparent to those skilled in the art that modifications and variations can be made without departing from the spirit and scope of the invention as defined by the appended claims.

What is claimed is:

1. A semiconductor device, comprising:
a semiconductor substrate having a front surface and a back surface and having a p-type impurity layer, a low-concentration n-type impurity layer, and an n-type impurity layer disposed in a backward direction from the front surface thereof, the n-type impurity layer having a high-concentration p-type impurity region therein and the n-type impurity layer and the high-concentration p-type impurity region being exposed to the back surface; and
a deep trench formed vertically in the semiconductor substrate to be open to the front surface of the semiconductor substrate and having a bottom surface connected to the high-concentration p-type impurity region.

2. The semiconductor device of claim 1, wherein the semiconductor substrate is a semiconductor wafer.

3. The semiconductor device of claim 1, wherein the p-type impurity region and the low-concentration n-type impurity layer have an n-type impurity layer formed therebetween.

4. The semiconductor device of claim 1, wherein the deep trench has an oxide film formed on an inner wall thereof.

5. The semiconductor device of claim 4, wherein the oxide film is protruded outwardly of the front surface of the semiconductor substrate.

6. The semiconductor device of claim 4, wherein the oxide film is formed of silicon oxide.

7. The semiconductor device of claim 1, wherein the deep trench is filled with a conductive material.

8. The semiconductor device of claim 7, wherein the conductive material includes polysilicon.

9. The semiconductor device of claim 1, wherein the deep trench and an adjacent deep trench have a gate trench formed therebetween, the gate trench being open to the front surface of the semiconductor substrate, and
a bottom portion of the gate trench is connected to the low-concentration n-type impurity layer.

10. The semiconductor device of claim 9, wherein the gate trench has an oxide film formed on an inner wall thereof.

11. The semiconductor device of claim 10, wherein the oxide film is protruded outwardly of the front surface of the semiconductor substrate.

12. The semiconductor device of claim 11, wherein the protruded oxide film extends to a portion of the front surface of the semiconductor substrate.

13. The semiconductor device of claim 10, wherein the oxide film is formed of silicon oxide.

14. The semiconductor device of claim 9, wherein the gate trench is filled with a conductive material.

15. The semiconductor device of claim 14, wherein the conductive material includes polysilicon.

16. The semiconductor device of claim 9, wherein a high-concentration p-type or n-type impurity region is formed around an opening of the gate trench of the front surface of the semiconductor substrate.

17. The semiconductor device of claim 1, wherein the n-type impurity layer is doped with n-type impurities including group V elements.

18. The semiconductor device of claim 1, wherein the p-type impurity layer and the p-type impurity region are doped with p-type impurities including group III elements.

19. The semiconductor device of claim 1, wherein the front surface of the semiconductor substrate is coated with a front metal film serving as an emitter electrode.

20. The semiconductor device of claim 19, wherein the front metal film is formed of aluminum or titanium.

21. The semiconductor device of claim 1, wherein the back surface of the semiconductor substrate is coated with a back metal film serving as a collector electrode.

22. The semiconductor device of claim 21, wherein the back metal film is formed of nickel or silver.

23. A method of manufacturing a semiconductor device, the method comprising:
preparing a semiconductor substrate having a front surface and a back surface and doped with low-concentration n-type impurities;
forming a deep trench vertically in the semiconductor substrate to be open to the front surface of the semiconductor substrate;
forming an n-type impurity layer by implanting n-type impurity ions into a bottom surface of the deep trench and performing a heat treatment thereon;
forming a high-concentration p-type impurity region within the n-type impurity layer by implanting p-type impurity ions into the bottom surface of the deep trench and performing a heat treatment thereon; and
forming a front metal film serving as an emitter electrode on the front surface of the semiconductor substrate.

24. The method of claim 23, wherein, in the forming of the deep trench, the deep trench is formed by an etching process.

25. The method of claim 23, wherein, in the forming of the n-type impurity layer, the heat treatment is performed at 800 to 1200° C.

26. The method of claim 23, wherein, in the forming of the high-concentration p-type impurity region, the heat treatment is performed at 800 to 1200° C.

27. The method of claim 23, wherein the front metal film is formed of aluminum or titanium.

28. The method of claim 23, wherein the n-type impurity layer is doped with n-type impurities including group V elements.

29. The method of claim 23, wherein the p-type impurity region is doped with p-type impurities including group III elements.

30. The method of claim 23, wherein the semiconductor substrate is a semiconductor wafer.

31. The method of claim 23, further comprising forming a gate trench open to the front surface of the semiconductor substrate and connected to a low-concentration n-type impurity layer, after the forming of the high-concentration p-type impurity region.

32. The method of claim 31, further comprising forming an oxide film in the deep trench and the gate trench after the forming of the gate trench.

33. The method of claim 32, further comprising burying a conductive material in the deep trench and the gate trench after the forming of the oxide film.

34. The method of claim 33, wherein the conductive material includes polysilicon.

35. The method of claim 33, further comprising performing back surface processing by polishing the back surface of the semiconductor substrate to expose the n-type impurity layer and the p-type impurity region after the burying of the conductive material.

36. The method of claim 35, further comprising forming a back metal film serving as a collector electrode on the back surface of the semiconductor substrate, after the back surface processing.

37. The method of claim 36, wherein the back metal film is formed of nickel or silver.
